(19) United States
(12) Patent Application Publication
(10) Pub. No.: US 2026/0276324 A1
(43) Pub. Date: Sep. 17, 2026

(54) Liquid Cooling System With Buffer Tank

(71) Applicant: Oracle International Corporation, Redwood Shores, CA (US)

(72) Inventors: Joshua (JP) Michael Buzzell, Providence Forge, VA (US); Craig Alderson Pennington, San Francisco, CA (US); Vali Sorell, Charlotte, NC (US); Christopher Palmer, Woodley (GB)

(73) Assignee: Oracle International Corporation, Redwood Shores, CA (US)

(21) Appl. No.: 19/564,840

(22) Filed: Mar. 12, 2026

Related U.S. Application Data
(60) Provisional application No. 63/771,264, filed on Mar. 13, 2025.

(51) Int. Cl. F28F 9/02; H05K 7/20

(52) U.S. Cl. CPC F28F 9/027; H05K 7/20272

(57) ABSTRACT

Techniques for using a buffer tank in a liquid cooling system are disclosed. A cooling system circulates coolant through pipes to cool devices. The cooling system returns heated coolant to a cooling unit via ingress pipes. The cooling unit cools the coolant to recirculate the coolant through the pipes. The system includes a buffer tank positioned between the cooling unit and ingress pipes. The buffer tank stores a reservoir of coolant liquid. As heated exhaust coolant enters the buffer tank, the heated exhaust coolant mixes with the reservoir of coolant liquid. The resulting mixed coolant is directed to the cooling unit to be cooled and recirculated through the system.

### INCORPORATION BY REFERENCE; DISCLAIMER

Each of the following applications and any parent patent applications (provisionals, non-provisionals, international, and foreign) to which this application claims priority to, directly or indirectly, are hereby incorporated by reference in their entirety to the same extent as if fully and explicitly recited herein. Any incorporation by reference is limited such that no subject matter is incorporated that is contrary to the explicit disclosure herein. The applications being incorporated by reference include at least: U.S. Application No. 63/771,264 filed on Mar. 13, 2025.

### TECHNICAL FIELD

The present disclosure relates to liquid cooling systems. In particular, the present disclosure relates to a liquid cooling system with a buffer tank.

### BACKGROUND

Cooling systems are a critical component in data center environments. Servers and networking equipment can generate a significant amount of heat. Overheated components can malfunction or fail, leading to potential data loss and costly repairs or replacements. High temperatures can also cause equipment to throttle its performance to prevent damage. Thus, effective cooling systems can help ensure that hardware operates at its optimal capacity. The increasing demand for artificial intelligence (AI) workloads, which generate more heat than traditional applications, is driving the adoption of more efficient cooling solutions like liquid cooling.

The approaches described in this section are approaches that could be pursued but not necessarily approaches that have been previously conceived or pursued. Therefore, unless otherwise indicated, it should not be assumed that any of the approaches described in this section qualify as prior art merely by virtue of their inclusion in this section.

### BRIEF DESCRIPTION OF DRAWINGS

The embodiments are illustrated by way of example and not by way of limitation in the figures of the accompanying drawings. References to “an” or “one” embodiment in this disclosure are not necessarily to the same embodiment, and they mean at least one. In the drawings:

FIG. 1 is a block diagram illustrating one pattern for implementing a cloud infrastructure as a service system according to at least one embodiment;

FIG. 2 is a block diagram illustrating another pattern for implementing a cloud infrastructure as a service system according to at least one embodiment;

FIG. 3 is a block diagram illustrating another pattern for implementing a cloud infrastructure as a service system according to at least one embodiment;

FIG. 4 is a block diagram illustrating another pattern for implementing a cloud infrastructure as a service system according to at least one embodiment;

FIG. 5 depicts a block diagram that illustrates a computer system in accordance with one or more embodiments;

FIG. 6 is a perspective view of a data center cooling system in accordance with one or more embodiments;

FIG. 7 illustrates a data center cooling system in accordance with one or more embodiments;

FIG. 8 illustrates an example set of operations for using a buffer tank in a liquid cooling system according to one or more embodiments;

FIG. 9 illustrates a buffer tank in accordance with one or more embodiments;

FIG. 10 illustrates a buffer tank that includes a liquid distribution component that includes a set of pipes in accordance with one or more embodiments; and

FIG. 11 illustrates a buffer tank that includes a sloped liquid distribution component in accordance with one or more embodiments.

### DESCRIPTION

### Introduction

In the following description, for the purposes of explanation, numerous specific details are set forth to provide a thorough understanding. One or more embodiments may be practiced without these specific details. Features described in one embodiment may be combined with features described in a different embodiment. In some examples, well-known structures and devices are described with reference to a block diagram form to avoid unnecessarily obscuring the present disclosure.

The term “cloud computing service” or “cloud service” generally refers to a service that is made available on demand, via scalable cloud infrastructure, typically over the internet or a private network, and managed by an external or in-house cloud provider (CP). The term “cloud infrastructure” (CI) generally refers to hardware and software components that provide computing, storage, and networking resources to deliver cloud services. There are various types or models of cloud services including Software-as-a-Service (SaaS), Platform-as-a-Service (PaaS), Infrastructure-as-a-Service (IaaS), Function-as-a-Service (FaaS), and others.

In a typical IaaS model, a CP provides virtualized and bare metal computing resources like servers, storage, and networking in a CP-operated data center. The CP is responsible for managing and maintaining the CI; the responsibilities span across multiple domains, such as operations, security, scalability, and compliance. Customers access the cloud services over the public Internet. Customers can use the CP CI to build their own customizable virtual or overlay networks and deploy customer resources. In other models, a CP provides similar virtualized and bare metal computing resources but in a customer-operated data center, which may include the customer's own CI. Customers access the CP CI and the customer CI over a private network. The combination of cloud services of the CP and the customer may be referred to as a “hybrid cloud.” In some cases, customers can serve as the CP's partner and sell the CP cloud services to further downstream customers. In yet other models, a first CP provides its virtualized and bare metal computing resources like servers, storage, and networking in the first CP's data center. A second CP provides its virtualized and bare metal computing resources also in the first CP's data center. A dedicated private network connects the CI of the two CPs. The combination of cloud services of the both CPs may be referred to as a “hybrid cloud.” In yet other models, a CP initially provisions CI to a customer, and then hands over all or a subset of the responsibilities associated with managing and maintaining the CI. For example, the customer may be primarily responsible for duties such as provisioning, repair, and maintenance of compute instances, while the CP retains other duties such as network management. Still other models may be used.

### General Overview

A cooling system circulates coolant liquid through a system to cool devices. The cooling system returns heated coolant to a cooling unit via ingress pipes. The cooling unit cools the coolant and recirculates the coolant through the system. The system includes a buffer tank positioned between the cooling unit and the ingress pipes. The buffer tank stores a reservoir of coolant liquid. As heated coolant enters the buffer tank, the heated coolant mixes with the reservoir of coolant. The mixed coolant is provided to the cooling unit to be cooled and recirculated through the system. By mixing heated coolant from exhaust pipes with reservoir coolant in the buffer tank, the buffer tank provides a buffer against spikes in temperatures of the heated coolant to the cooling unit. The buffer tank has an effect of evening out spikes in temperatures of incoming heated coolant. For example, if an event in the system results in a spike in the temperature of the heated coolant, the heated coolant mixes with reservoir coolant that has a lower temperature to provide a mixed coolant with an intermediate temperature to the cooling unit.

One or more embodiments connect two or more cooling systems that cool two or more sets of computing devices. The cooling systems may be connected by valves to selectively permit the flow of coolant and heated coolant between the cooling systems. If one system detects a spike in temperature of a heated coolant, the system may open the valves connecting the cooling systems to permit circulation of coolant and heated coolant between the systems. The circulation of coolant and heated coolant between the cooling systems has an effect of averaging temperatures of the coolant and heated coolant between the systems.

### Examples of Cloud Infrastructure

As noted above, infrastructure as a service (IaaS) is one particular type of cloud computing. For IaaS, the infrastructure (CI) provided by a CP can be configured to provide virtualized computing resources over a public network (e.g., the Internet). In an IaaS model, a CP can host the infrastructure components (e.g., servers, storage devices, network nodes (e.g., hardware), deployment software, platform virtualization (e.g., a hypervisor layer), or the like). CI thus provides infrastructure and a set of complementary cloud services that enable customers to build and run a wide range of applications and services in a highly available hosted distributed environment. The customer does not manage or control the underlying physical resources provided by CI but has control over operating systems, storage, and deployed applications; and possibly limited control of select networking components (e.g., firewalls).

In some cases, an IaaS provider may also supply a variety of services to accompany those infrastructure components (example services include billing software, monitoring software, logging software, load balancing software, clustering software, etc.). Thus, as these services may be policy-driven, IaaS users may be able to implement policies to drive load balancing to maintain application availability and performance. When a customer subscribes to or registers for an IaaS service provided by a CP, a tenancy, or account, is created for the customer. A tenancy is a secure and isolated partition within the CI where the customer can create, organize, and administer their cloud resources.

In some instances, IaaS customers may access resources and services through a wide area network (WAN), such as the Internet, and can use the cloud provider's services to install the remaining elements of an application stack. For example, the user can log in to the IaaS platform to create virtual machines (VMs), install operating systems (OSs) on each VM, deploy middleware such as databases, create storage buckets for workloads and backups, and even install enterprise software into that VM. Customers can then use the provider's services to perform various functions, including balancing network traffic, troubleshooting application issues, monitoring performance, managing disaster recovery, etc.

The CP may provide a console that enables customers and network administrators to configure, access, and manage resources deployed in the cloud using CI resources. In certain embodiments, the console provides a web-based user interface that can be used to access and manage CI. In some implementations, the console is a web-based application provided by the CP.

CI may support single-tenancy or multi-tenancy architectures. In a single tenancy architecture, a software (e.g., an application, a database) or a hardware component (e.g., a host machine or a server) of the CI serves a single customer or tenant. In a multi-tenancy architecture, a software or a hardware component of the CI serves multiple customers or tenants. Thus, in a multi-tenancy architecture, CI resources are shared between multiple customers or tenants. In a multi-tenancy situation, precautions are taken, and safeguards put in place within CI to ensure that each tenant's data is isolated and remains invisible to other tenants.

In certain embodiments, cloud resources within CI may include, for example, compute instances, block storage volumes, virtual cloud networks (VCNs), subnets, databases, third-party applications, SaaS applications, on-premise software, and web applications. Each cloud resource is assigned a unique identifier called a Cloud Identifier (CID). This identifier is included as part of the resource's information and can be used to manage the resource, for example, via a Console or through APIs. An example syntax for a CID is:

cid1.<RESOURCE TYPE>.<REALM>.[REGION][.FUTURE USE].<UNIQUE ID>

where,
cid1: The literal string indicating the version of the CID; resource type: The type of resource (for example, instance, volume, VCN, subnet, user, group, and so on);
realm: The realm the resource is in. Example values are “c1” for the commercial realm, “c2” for the Government Cloud realm, or “c3” for the Federal Government Cloud realm, etc. Each realm may have its own domain name;
region: The region the resource is in. If the region is not applicable to the resource, this part might be blank;
future use: Reserved for future use.
unique ID: The unique portion of the ID. The format may vary depending on the type of resource or service.

In some examples, IaaS deployment is the process of putting a new application, or a new version of an application, onto a prepared application server or the like. It may also include the process of preparing the server (e.g., installing libraries, daemons, etc.). This is often managed by the cloud provider, below the hypervisor layer (e.g., the servers, storage, network hardware, and virtualization). Thus, the customer may be responsible for handling (OS), middleware, and/or application deployment (e.g., on self-service virtual machines (e.g., that can be spun up on demand) or the like.

In some examples, IaaS provisioning may refer to acquiring computers or virtual hosts for use, and even installing needed libraries or services on them. In most cases, deployment does not include provisioning, and the provisioning may need to be performed first.

In some cases, there are two different challenges for IaaS provisioning. First, there is the initial challenge of provisioning the initial set of infrastructure before anything is running. Second, there is the challenge of evolving the existing infrastructure (e.g., adding new services, changing services, removing services, etc.) once everything has been provisioned. In some cases, these two challenges may be addressed by enabling the configuration of the infrastructure to be defined declaratively. In other words, the infrastructure (e.g., what components are needed and how they interact) can be defined by one or more configuration files. Thus, the overall topology of the infrastructure (e.g., what resources depend on which, and how they each work together) can be described declaratively. In some instances, once the topology is defined, a workflow can be generated that creates and/or manages the different components described in the configuration files.

In some examples, an infrastructure may have many interconnected elements. For example, there may be one or more virtual private clouds (VPCs) (e.g., a potentially on-demand pool of configurable and/or shared computing resources), also known as a core network. In some examples, there may also be one or more inbound/outbound traffic group rules provisioned to define how the inbound and/or outbound traffic of the network will be set up and one or more virtual machines (VMs). Other infrastructure elements may also be provisioned, such as a load balancer, a database, or the like. As more and more infrastructure elements are desired and/or added, the infrastructure may incrementally evolve.

In some instances, continuous deployment techniques may be employed to enable deployment of infrastructure code across various virtual computing environments. Additionally, the described techniques can enable infrastructure management within these environments. In some examples, service teams can write code that is desired to be deployed to one or more, but often many, different production environments (e.g., across various different geographic locations, sometimes spanning the entire world). However, in some examples, the infrastructure on which the code will be deployed is required to first be set up. In some instances, the provisioning can be done manually, a provisioning tool may be utilized to provision the resources, and/or deployment tools may be utilized to deploy the code once the infrastructure is provisioned.

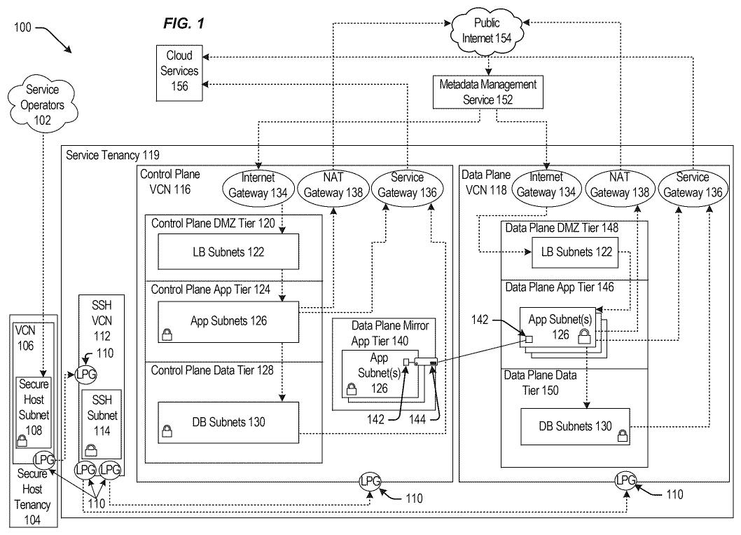

FIG. 1 is a block diagram 100 illustrating an example pattern of an IaaS architecture, according to at least one embodiment. Service operators 102 can be communicatively coupled to a secure host tenancy 104 that can include a virtual cloud network (VCN) 106 and a secure host subnet 108. In some examples, the service operators 102 may be using one or more client computing devices, which may be portable handheld devices (e.g., an iPhone®, cellular telephone, an iPad®, computing tablet, a personal digital assistant (PDA)) or wearable devices (e.g., a Google Glass® head mounted display), running software such as Microsoft Windows Mobile®, and/or a variety of mobile operating systems such as iOS, Windows Phone, Android, BlackBerry 8, Palm OS, and the like, and being Internet, e-mail, short message service (SMS), Blackberry®, or other communication protocol enabled. Alternatively, the client computing devices can be general purpose personal computers including, by way of example, personal computers and/or laptop computers running various versions of Microsoft Windows®, Apple Macintosh®, and/or Linux operating systems. The client computing devices can be workstation computers running any of a variety of commercially-available UNIX® or UNIX-like operating systems, including without limitation the variety of GNU/Linux operating systems, such as for example, Google Chrome OS. Alternatively, or in addition, client computing devices may be any other electronic device, such as a thin-client computer, an Internet-enabled gaming system (e.g., a Microsoft Xbox gaming console with or without a Kinect® gesture input device), and/or a personal messaging device, capable of communicating over a network that can access the VCN 106 and/or the Internet.

The VCN 106 can include a local peering gateway (LPG) 110 that can be communicatively coupled to a secure shell (SSH) VCN 112 via an LPG 110 contained in the SSH VCN 112. The SSH VCN 112 can include an SSH subnet 114, and the SSH VCN 112 can be communicatively coupled to a control plane VCN 116 via the LPG 110 contained in the control plane VCN 116. Also, the SSH VCN 112 can be communicatively coupled to a data plane VCN 118 via an LPG 110. The control plane VCN 116 and the data plane VCN 118 can be contained in a service tenancy 119 that can be owned and/or operated by the IaaS provider.

The control plane VCN 116 can include a control plane demilitarized zone (DMZ) tier 120 that acts as a perimeter network (e.g., portions of a corporate network between the corporate intranet and external networks). The DMZ-based servers may have restricted responsibilities and help keep breaches contained. Additionally, the DMZ tier 120 can include one or more load balancer (LB) subnet(s) 122, a control plane app tier 124 that can include app subnet(s) 126, a control plane data tier 128 that can include database (DB) subnet(s) 130 (e.g., frontend DB subnet(s) and/or backend DB subnet(s)). The LB subnet(s) 122 contained in the control plane DMZ tier 120 can be communicatively coupled to the app subnet(s) 126 contained in the control plane app tier 124 and an Internet gateway 134 that can be contained in the control plane VCN 116, and the app subnet(s) 126 can be communicatively coupled to the DB subnet(s) 130 contained in the control plane data tier 128 and a service gateway 136 and a network address translation (NAT) gateway 138. The control plane VCN 116 can include the service gateway 136 and the NAT gateway 138.

The control plane VCN 116 can include a data plane mirror app tier 140 that can include app subnet(s) 126. The app subnet(s) 126 contained in the data plane mirror app tier 140 can include a virtual network interface controller (VNIC) 142 that can execute a compute instance 144. The compute instance 144 can communicatively couple the app subnet(s) 126 of the data plane mirror app tier 140 to app subnet(s) 126 that can be contained in a data plane app tier 146.

The data plane VCN 118 can include the data plane app tier 146, a data plane DMZ tier 148, and a data plane data tier 150. The data plane DMZ tier 148 can include LB subnet(s) 122 that can be communicatively coupled to the app subnet(s) 126 of the data plane app tier 146 and the Internet gateway 134 of the data plane VCN 118. The app subnet(s) 126 can be communicatively coupled to the service gateway 136 of the data plane VCN 118 and the NAT gateway 138 of the data plane VCN 118. The data plane data tier 150 can also include the DB subnet(s) 130 that can be communicatively coupled to the app subnet(s) 126 of the data plane app tier 146.

The Internet gateway 134 of the control plane VCN 116 and of the data plane VCN 118 can be communicatively coupled to a metadata management service 152 that can be communicatively coupled to public Internet 154. Public Internet 154 can be communicatively coupled to the NAT gateway 138 of the control plane VCN 116 and of the data plane VCN 118. The service gateway 136 of the control plane VCN 116 and of the data plane VCN 118 can be communicatively couple to cloud services 156.

In some examples, the service gateway 136 of the control plane VCN 116 or of the data plane VCN 118 can make application programming interface (API) calls to cloud services 156 without going through public Internet 154. The API calls to cloud services 156 from the service gateway 136 can be one-way: the service gateway 136 can make API calls to cloud services 156, and cloud services 156 can send requested data to the service gateway 136. But, cloud services 156 may not initiate API calls to the service gateway 136.

In some examples, the secure host tenancy 104 can be directly connected to the service tenancy 119, which may be otherwise isolated. The secure host subnet 108 can communicate with the SSH subnet 114 through an LPG 110 that may enable two-way communication over an otherwise isolated system. Connecting the secure host subnet 108 to the SSH subnet 114 may give the secure host subnet 108 access to other entities within the service tenancy 119.

The control plane VCN 116 may allow users of the service tenancy 119 to set up or otherwise provision desired resources. Desired resources provisioned in the control plane VCN 116 may be deployed or otherwise used in the data plane VCN 118. In some examples, the control plane VCN 116 can be isolated from the data plane VCN 118, and the data plane mirror app tier 140 of the control plane VCN 116 can communicate with the data plane app tier 146 of the data plane VCN 118 via VNICs 142 that can be contained in the data plane mirror app tier 140 and the data plane app tier 146.

In some examples, users of the system, or customers, can make requests, for example create, read, update, or delete (CRUD) operations, through public Internet 154 that can communicate the requests to the metadata management service 152. The metadata management service 152 can communicate the request to the control plane VCN 116 through the Internet gateway 134. The request can be received by the LB subnet(s) 122 contained in the control plane DMZ tier 120. The LB subnet(s) 122 may determine that the request is valid, and in response to this determination, the LB subnet(s) 122 can transmit the request to app subnet(s) 126 contained in the control plane app tier 124. If the request is validated and requires a call to public Internet 154, the call to public Internet 154 may be transmitted to the NAT gateway 138 that can make the call to public Internet 154. Metadata that may be desired to be stored by the request can be stored in the DB subnet(s) 130.

In some examples, the data plane mirror app tier 140 can facilitate direct communication between the control plane VCN 116 and the data plane VCN 118. For example, changes, updates, or other suitable modifications to configuration may be desired to be applied to the resources contained in the data plane VCN 118. Via a VNIC 142, the control plane VCN 116 can directly communicate with, and can thereby execute the changes, updates, or other suitable modifications to configuration to, resources contained in the data plane VCN 118.

In some embodiments, the control plane VCN 116 and the data plane VCN 118 can be contained in the service tenancy 119. In this case, the user, or the customer, of the system may not own or operate either the control plane VCN 116 or the data plane VCN 118. Instead, the IaaS provider may own or operate the control plane VCN 116 and the data plane VCN 118, both of which may be contained in the service tenancy 119. This embodiment can enable isolation of networks that may prevent users or customers from interacting with other users', or other customers', resources. Also, this embodiment may allow users or customers of the system to store databases privately without needing to rely on public Internet 154, which may not have a desired level of threat prevention, for storage.

In other embodiments, the LB subnet(s) 122 contained in the control plane VCN 116 can be configured to receive a signal from the service gateway 136. In this embodiment, the control plane VCN 116 and the data plane VCN 118 may be configured to be called by a customer of the IaaS provider without calling public Internet 154. Customers of the IaaS provider may desire this embodiment since database(s) that the customers use may be controlled by the IaaS provider and may be stored on the service tenancy 119, which may be isolated from public Internet 154.

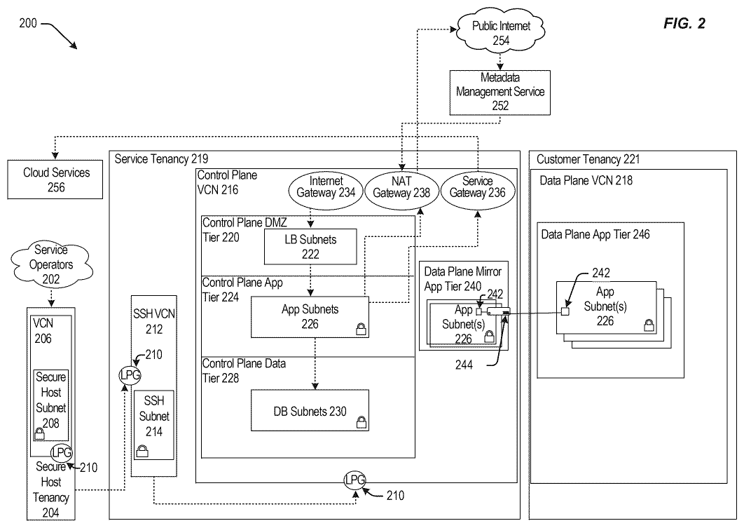

FIG. 2 is a block diagram 200 illustrating another example pattern of an IaaS architecture, according to at least one embodiment. Service operators 202 (e.g., service operators 102 of FIG. 1) can be communicatively coupled to a secure host tenancy 204 (e.g., the secure host tenancy 104 of FIG. 1) that can include a virtual cloud network (VCN) 206 (e.g., the VCN 106 of FIG. 1) and a secure host subnet 208 (e.g., the secure host subnet 108 of FIG. 1). The VCN 206 can include a local peering gateway (LPG) 210 (e.g., the LPG 110 of FIG. 1) that can be communicatively coupled to a secure shell (SSH) VCN 212 (e.g., the SSH VCN 112 of FIG. 1) via an LPG 110 contained in the SSH VCN 212. The SSH VCN 212 can include an SSH subnet 214 (e.g., the SSH subnet 114 of FIG. 1), and the SSH VCN 212 can be communicatively coupled to a control plane VCN 216 (e.g., the control plane VCN 116 of FIG. 1) via an LPG 210 contained in the control plane VCN 216. The control plane VCN 216 can be contained in a service tenancy 219 (e.g., the service tenancy 119 of FIG. 1), and the data plane VCN 218 (e.g., the data plane VCN 118 of FIG. 1) can be contained in a customer tenancy 221 that may be owned or operated by users, or customers, of the system.

The control plane VCN 216 can include a control plane DMZ tier 220 (e.g., the control plane DMZ tier 120 of FIG. 1) that can include LB subnet(s) 222 (e.g., LB subnet(s) 122 of FIG. 1), a control plane app tier 224 (e.g., the control plane app tier 124 of FIG. 1) that can include app subnet(s) 226 (e.g., app subnet(s) 126 of FIG. 1), a control plane data tier 228 (e.g., the control plane data tier 128 of FIG. 1) that can include database (DB) subnet(s) 230 (e.g., similar to DB subnet(s) 130 of FIG. 1). The LB subnet(s) 222 contained in the control plane DMZ tier 220 can be communicatively coupled to the app subnet(s) 226 contained in the control plane app tier 224 and an Internet gateway 234 (e.g., the Internet gateway 134 of FIG. 1) that can be contained in the control plane VCN 216, and the app subnet(s) 226 can be communicatively coupled to the DB subnet(s) 230 contained in the control plane data tier 228 and a service gateway 236 (e.g., the service gateway 136 of FIG. 1) and a network address translation (NAT) gateway 238 (e.g., the NAT gateway 138 of FIG. 1). The control plane VCN 216 can include the service gateway 236 and the NAT gateway 238.

The control plane VCN 216 can include a data plane mirror app tier 240 (e.g., the data plane mirror app tier 140 of FIG. 1) that can include app subnet(s) 226. The app subnet(s) 226 contained in the data plane mirror app tier 240 can include a virtual network interface controller (VNIC) 242 (e.g., the VNIC of 142) that can execute a compute instance 244 (e.g., similar to the compute instance 144 of FIG. 1). The compute instance 244 can facilitate communication between the app subnet(s) 226 of the data plane mirror app tier 240 and the app subnet(s) 226 that can be contained in a data plane app tier 246 (e.g., the data plane app tier 146 of FIG. 1) via the VNIC 242 contained in the data plane mirror app tier 240 and the VNIC 242 contained in the data plane app tier 246.

The Internet gateway 234 contained in the control plane VCN 216 can be communicatively coupled to a metadata management service 252 (e.g., the metadata management service 152 of FIG. 1) that can be communicatively coupled to public Internet 254 (e.g., public Internet 154 of FIG. 1). Public Internet 254 can be communicatively coupled to the NAT gateway 238 contained in the control plane VCN 216. The service gateway 236 contained in the control plane VCN 216 can be communicatively couple to cloud services 256 (e.g., cloud services 156 of FIG. 1).

In some examples, the data plane VCN 218 can be contained in the customer tenancy 221. In this case, the IaaS provider may provide the control plane VCN 216 for each customer, and the IaaS provider may, for each customer, set up a unique compute instance 244 that is contained in the service tenancy 219. Each compute instance 244 may allow communication between the control plane VCN 216, contained in the service tenancy 219, and the data plane VCN 218 that is contained in the customer tenancy 221. The compute instance 244 may allow resources, that are provisioned in the control plane VCN 216 that is contained in the service tenancy 219, to be deployed or otherwise used in the data plane VCN 218 that is contained in the customer tenancy 221.

In other examples, the customer of the IaaS provider may have databases that live in the customer tenancy 221. In this example, the control plane VCN 216 can include the data plane mirror app tier 240 that can include app subnet(s) 226. The data plane mirror app tier 240 can reside in the data plane VCN 218, but the data plane mirror app tier 240 may not live in the data plane VCN 218. That is, the data plane mirror app tier 240 may have access to the customer tenancy 221, but the data plane mirror app tier 240 may not exist in the data plane VCN 218 or be owned or operated by the customer of the IaaS provider. The data plane mirror app tier 240 may be configured to make calls to the data plane VCN 218 but may not be configured to make calls to any entity contained in the control plane VCN 216. The customer may desire to deploy or otherwise use resources in the data plane VCN 218 that are provisioned in the control plane VCN 216, and the data plane mirror app tier 240 can facilitate the desired deployment, or other usage of resources, of the customer.

In some embodiments, the customer of the IaaS provider can apply filters to the data plane VCN 218. In this embodiment, the customer can determine what the data plane VCN 218 can access, and the customer may restrict access to public Internet 254 from the data plane VCN 218. The IaaS provider may not be able to apply filters or otherwise control access of the data plane VCN 218 to any outside networks or databases. Applying filters and controls by the customer onto the data plane VCN 218, contained in the customer tenancy 221, can help isolate the data plane VCN 218 from other customers and from public Internet 254.

In some embodiments, cloud services 256 can be called by the service gateway 236 to access services that may not exist on public Internet 254, on the control plane VCN 216, or on the data plane VCN 218. The connection between cloud services 256 and the control plane VCN 216 or the data plane VCN 218 may not be live or continuous. Cloud services 256 may exist on a different network owned or operated by the IaaS provider. Cloud services 256 may be configured to receive calls from the service gateway 236 and may be configured to not receive calls from public Internet 254. Some cloud services 256 may be isolated from other cloud services 256, and the control plane VCN 216 may be isolated from cloud services 256 that may not be in the same region as the control plane VCN 216. For example, the control plane VCN 216 may be located in “Region 1,” and cloud service “Deployment 1,” may be located in Region 1 and in “Region 2.” If a call to Deployment 1 is made by the service gateway 236 contained in the control plane VCN 216 located in Region 1, the call may be transmitted to Deployment 1 in Region 1. In this example, the control plane VCN 216, or Deployment 1 in Region 1, may not be communicatively coupled to, or otherwise in communication with, Deployment 1 in Region 2.

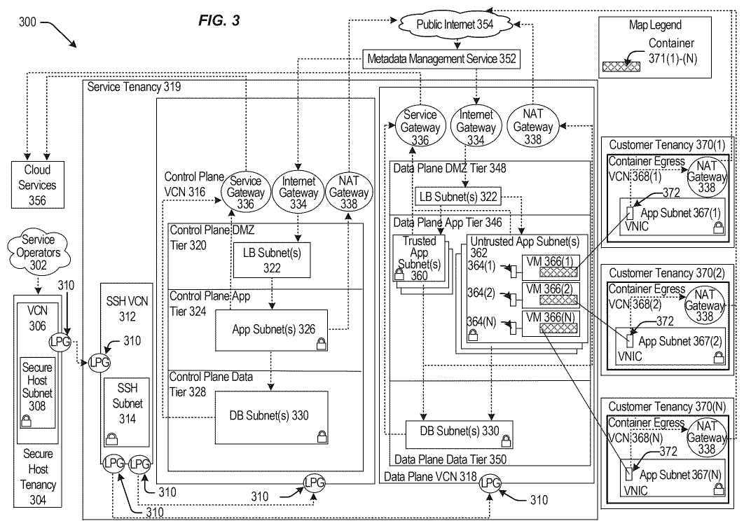

FIG. 3 is a block diagram 300 illustrating another example pattern of an IaaS architecture, according to at least one embodiment. Service operators 302 (e.g., service operators 102 of FIG. 1) can be communicatively coupled to a secure host tenancy 304 (e.g., the secure host tenancy 104 of FIG. 1) that can include a virtual cloud network (VCN) 306 (e.g., the VCN 106 of FIG. 1) and a secure host subnet 308 (e.g., the secure host subnet 108 of FIG. 1). The VCN 306 can include an LPG 310 (e.g., the LPG 110 of FIG. 1) that can be communicatively coupled to an SSH VCN 312 (e.g., the SSH VCN 112 of FIG. 1) via an LPG 310 contained in the SSH VCN 312. The SSH VCN 312 can include an SSH subnet 314 (e.g., the SSH subnet 114 of FIG. 1), and the SSH VCN 312 can be communicatively coupled to a control plane VCN 316 (e.g., the control plane VCN 116 of FIG. 1) via an LPG 310 contained in the control plane VCN 316 and to a data plane VCN 318 (e.g., the data plane 118 of FIG. 1) via an LPG 310 contained in the data plane VCN 318. The control plane VCN 316 and the data plane VCN 318 can be contained in a service tenancy 319 (e.g., the service tenancy 119 of FIG. 1).

The control plane VCN 316 can include a control plane DMZ tier 320 (e.g., the control plane DMZ tier 120 of FIG. 1) that can include load balancer (LB) subnet(s) 322 (e.g., LB subnet(s) 122 of FIG. 1), a control plane app tier 324 (e.g., the control plane app tier 124 of FIG. 1) that can include app subnet(s) 326 (e.g., similar to app subnet(s) 126 of FIG. 1), a control plane data tier 328 (e.g., the control plane data tier 128 of FIG. 1) that can include DB subnet(s) 330. The LB subnet(s) 322 contained in the control plane DMZ tier 320 can be communicatively coupled to the app subnet(s) 326 contained in the control plane app tier 324 and to an Internet gateway 334 (e.g., the Internet gateway 134 of FIG. 1) that can be contained in the control plane VCN 316, and the app subnet(s) 326 can be communicatively coupled to the DB subnet(s) 330 contained in the control plane data tier 328 and to a service gateway 336 (e.g., the service gateway of FIG. 1) and a network address translation (NAT) gateway 338 (e.g., the NAT gateway 138 of FIG. 1). The control plane VCN 316 can include the service gateway 336 and the NAT gateway 338.

The data plane VCN 318 can include a data plane app tier 346 (e.g., the data plane app tier 146 of FIG. 1), a data plane DMZ tier 348 (e.g., the data plane DMZ tier 148 of FIG. 1), and a data plane data tier 350 (e.g., the data plane data tier 150 of FIG. 1). The data plane DMZ tier 348 can include LB subnet(s) 322 that can be communicatively coupled to trusted app subnet(s) 360 and untrusted app subnet(s) 362 of the data plane app tier 346 and the Internet gateway 334 contained in the data plane VCN 318. The trusted app subnet(s) 360 can be communicatively coupled to the service gateway 336 contained in the data plane VCN 318, the NAT gateway 338 contained in the data plane VCN 318, and DB subnet(s) 330 contained in the data plane data tier 350. The untrusted app subnet(s) 362 can be communicatively coupled to the service gateway 336 contained in the data plane VCN 318 and DB subnet(s) 330 contained in the data plane data tier 350. The data plane data tier 350 can include DB subnet(s) 330 that can be communicatively coupled to the service gateway 336 contained in the data plane VCN 318.

The untrusted app subnet(s) 362 can include one or more primary VNICs 364(1)-(N) that can be communicatively coupled to tenant virtual machines (VMs) 366(1)-(N). Each tenant VM 366(1)-(N) can be communicatively coupled to a respective app subnet 367(1)-(N) that can be contained in respective container egress VCNs 368(1)-(N) that can be contained in respective customer tenancies 370(1)-(N). Respective secondary VNICs 372(1)-(N) can facilitate communication between the untrusted app subnet(s) 362 contained in the data plane VCN 318 and the app subnet contained in the container egress VCNs 368(1)-(N). Each container egress VCNs 368(1)-(N) can include a NAT gateway 338 that can be communicatively coupled to public Internet 354 (e.g., public Internet 154 of FIG. 1).

The Internet gateway 334 contained in the control plane VCN 316 and contained in the data plane VCN 318 can be communicatively coupled to a metadata management service 352 (e.g., the metadata management system 152 of FIG. 1) that can be communicatively coupled to public Internet 354. Public Internet 354 can be communicatively coupled to the NAT gateway 338 contained in the control plane VCN 316 and contained in the data plane VCN 318. The service gateway 336 contained in the control plane VCN 316 and contained in the data plane VCN 318 can be communicatively couple to cloud services 356.

In some embodiments, the data plane VCN 318 can be integrated with customer tenancies 370. This integration can be useful or desirable for customers of the IaaS provider in some cases such as a case that may desire support when executing code. The customer may provide code to run that may be destructive, may communicate with other customer resources, or may otherwise cause undesirable effects. In response to this, the IaaS provider may determine whether to run code given to the IaaS provider by the customer.

In some examples, the customer of the IaaS provider may grant temporary network access to the IaaS provider and request a function to be attached to the data plane app tier 346. Code to run the function may be executed in the VMs 366(1)-(N), and the code may not be configured to run anywhere else on the data plane VCN 318. Each VM 366(1)-(N) may be connected to one customer tenancy 370. Respective containers 371(1)-(N) contained in the VMs 366(1)-(N) may be configured to run the code. In this case, there can be a dual isolation (e.g., the containers 371(1)-(N) running code, where the containers 371(1)-(N) may be contained in at least the VM 366(1)-(N) that are contained in the untrusted app subnet(s) 362), which may help prevent incorrect or otherwise undesirable code from damaging the network of the IaaS provider or from damaging a network of a different customer. The containers 371(1)-(N) may be communicatively coupled to the customer tenancy 370 and may be configured to transmit or receive data from the customer tenancy 370. The containers 371(1)-(N) may not be configured to transmit or receive data from any other entity in the data plane VCN 318. Upon completion of running the code, the IaaS provider may kill or otherwise dispose of the containers 371(1)-(N).

In some embodiments, the trusted app subnet(s) 360 may run code that may be owned or operated by the IaaS provider. In this embodiment, the trusted app subnet(s) 360 may be communicatively coupled to the DB subnet(s) 330 and be configured to execute CRUD operations in the DB subnet(s) 330. The untrusted app subnet(s) 362 may be communicatively coupled to the DB subnet(s) 330, but in this embodiment, the untrusted app subnet(s) may be configured to execute read operations in the DB subnet(s) 330. The containers 371(1)-(N) that can be contained in the VM 366(1)-(N) of each customer and that may run code from the customer may not be communicatively coupled with the DB subnet(s) 330.

In other embodiments, the control plane VCN 316 and the data plane VCN 318 may not be directly communicatively coupled. In this embodiment, there may be no direct communication between the control plane VCN 316 and the data plane VCN 318. However, communication can occur indirectly through at least one method. An LPG 310 may be established by the IaaS provider that can facilitate communication between the control plane VCN 316 and the data plane VCN 318. In another example, the control plane VCN 316 or the data plane VCN 318 can make a call to cloud services 356 via the service gateway 336. For example, a call to cloud services 356 from the control plane VCN 316 can include a request for a service that can communicate with the data plane VCN 318.

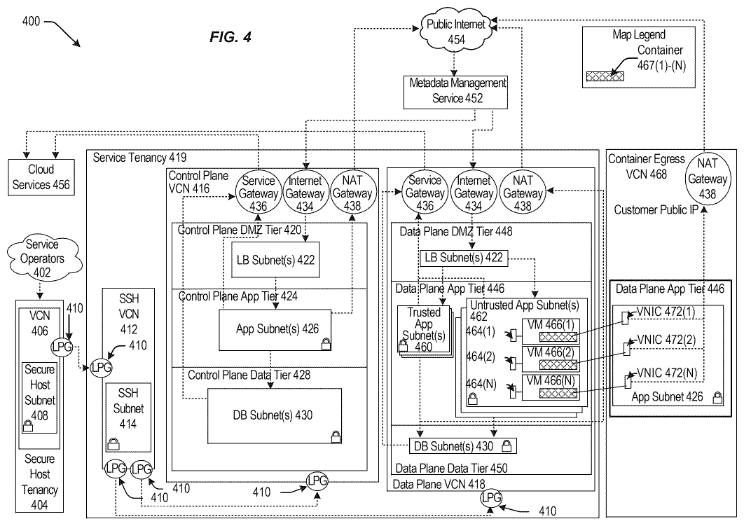

FIG. 4 is a block diagram 400 illustrating another example pattern of an IaaS architecture, according to at least one embodiment. Service operators 402 (e.g., service operators 102 of FIG. 1) can be communicatively coupled to a secure host tenancy 404 (e.g., the secure host tenancy 104 of FIG. 1) that can include a virtual cloud network (VCN) 406 (e.g., the VCN 106 of FIG. 1) and a secure host subnet 408 (e.g., the secure host subnet 108 of FIG. 1). The VCN 406 can include an LPG 410 (e.g., the LPG 110 of FIG. 1) that can be communicatively coupled to an SSH VCN 412 (e.g., the SSH VCN 112 of FIG. 1) via an LPG 410 contained in the SSH VCN 412. The SSH VCN 412 can include an SSH subnet 414 (e.g., the SSH subnet 114 of FIG. 1), and the SSH VCN 412 can be communicatively coupled to a control plane VCN 416 (e.g., the control plane VCN 116 of FIG. 1) via an LPG 410 contained in the control plane VCN 416 and to a data plane VCN 418 (e.g., the data plane 118 of FIG. 1) via an LPG 410 contained in the data plane VCN 418. The control plane VCN 416 and the data plane VCN 418 can be contained in a service tenancy 419 (e.g., the service tenancy 119 of FIG. 1).

The control plane VCN 416 can include a control plane DMZ tier 420 (e.g., the control plane DMZ tier 120 of FIG. 1) that can include LB subnet(s) 422 (e.g., LB subnet(s) 122 of FIG. 1), a control plane app tier 424 (e.g., the control plane app tier 124 of FIG. 1) that can include app subnet(s) 426 (e.g., app subnet(s) 126 of FIG. 1), a control plane data tier 428 (e.g., the control plane data tier 128 of FIG. 1) that can include DB subnet(s) 430 (e.g., DB subnet(s) 330 of FIG. 3). The LB subnet(s) 422 contained in the control plane DMZ tier 420 can be communicatively coupled to the app subnet(s) 426 contained in the control plane app tier 424 and to an Internet gateway 434 (e.g., the Internet gateway 134 of FIG. 1) that can be contained in the control plane VCN 416, and the app subnet(s) 426 can be communicatively coupled to the DB subnet(s) 430 contained in the control plane data tier 428 and to a service gateway 436 (e.g., the service gateway of FIG. 1) and a network address translation (NAT) gateway 438 (e.g., the NAT gateway 138 of FIG. 1). The control plane VCN 416 can include the service gateway 436 and the NAT gateway 438.

The data plane VCN 418 can include a data plane app tier 446 (e.g., the data plane app tier 146 of FIG. 1), a data plane DMZ tier 448 (e.g., the data plane DMZ tier 148 of FIG. 1), and a data plane data tier 450 (e.g., the data plane data tier 150 of FIG. 1). The data plane DMZ tier 448 can include LB subnet(s) 422 that can be communicatively coupled to trusted app subnet(s) 460 (e.g., trusted app subnet(s) 360 of FIG. 3) and untrusted app subnet(s) 462 (e.g., untrusted app subnet(s) 362 of FIG. 3) of the data plane app tier 446 and the Internet gateway 434 contained in the data plane VCN 418. The trusted app subnet(s) 460 can be communicatively coupled to the service gateway 436 contained in the data plane VCN 418, the NAT gateway 438 contained in the data plane VCN 418, and DB subnet(s) 430 contained in the data plane data tier 450. The untrusted app subnet(s) 462 can be communicatively coupled to the service gateway 436 contained in the data plane VCN 418 and DB subnet(s) 430 contained in the data plane data tier 450. The data plane data tier 450 can include DB subnet(s) 430 that can be communicatively coupled to the service gateway 436 contained in the data plane VCN 418.

The untrusted app subnet(s) 462 can include primary VNICs 464(1)-(N) that can be communicatively coupled to tenant virtual machines (VMs) 466(1)-(N) residing within the untrusted app subnet(s) 462. Each tenant VM 466(1)-(N) can run code in a respective container 467(1)-(N), and be communicatively coupled to an app subnet 426 that can be contained in a data plane app tier 446 that can be contained in a container egress VCN 468. Respective secondary VNICs 472(1)-(N) can facilitate communication between the untrusted app subnet(s) 462 contained in the data plane VCN 418 and the app subnet contained in the container egress VCN 468. The container egress VCN can include a NAT gateway 438 that can be communicatively coupled to public Internet 454 (e.g., public Internet 154 of FIG. 1).

The Internet gateway 434 contained in the control plane VCN 416 and contained in the data plane VCN 418 can be communicatively coupled to a metadata management service 452 (e.g., the metadata management system 152 of FIG. 1) that can be communicatively coupled to public Internet 454. Public Internet 454 can be communicatively coupled to the NAT gateway 438 contained in the control plane VCN 416 and contained in the data plane VCN 418. The service gateway 436 contained in the control plane VCN 416 and contained in the data plane VCN 418 can be communicatively couple to cloud services 456.

In some examples, the pattern illustrated by the architecture of block diagram 400 of FIG. 4 may be considered an exception to the pattern illustrated by the architecture of block diagram 300 of FIG. 3 and may be desirable for a customer of the IaaS provider if the IaaS provider cannot directly communicate with the customer (e.g., a disconnected region). The respective containers 467(1)-(N) that are contained in the VMs 466(1)-(N) for each customer can be accessed in real-time by the customer. The containers 467(1)-(N) may be configured to make calls to respective secondary VNICs 472(1)-(N) contained in app subnet(s) 426 of the data plane app tier 446 that can be contained in the container egress VCN 468. The secondary VNICs 472(1)-(N) can transmit the calls to the NAT gateway 438 that may transmit the calls to public Internet 454. In this example, the containers 467(1)-(N) that can be accessed in real-time by the customer can be isolated from the control plane VCN 416 and can be isolated from other entities contained in the data plane VCN 418. The containers 467(1)-(N) may also be isolated from resources from other customers.

In other examples, the customer can use the containers 467(1)-(N) to call cloud services 456. In this example, the customer may run code in the containers 467(1)-(N) that requests a service from cloud services 456. The containers 467(1)-(N) can transmit this request to the secondary VNICs 472(1)-(N) that can transmit the request to the NAT gateway that can transmit the request to public Internet 454. Public Internet 454 can transmit the request to LB subnet(s) 422 contained in the control plane VCN 416 via the Internet gateway 434. In response to determining the request is valid, the LB subnet(s) can transmit the request to app subnet(s) 426 that can transmit the request to cloud services 456 via the service gateway 436.

It should be appreciated that IaaS architectures 100, 200, 300, 400 depicted in the figures may have other components than those depicted. Further, the embodiments shown in the figures are only some examples of a cloud infrastructure system that may incorporate an embodiment of the disclosure. In some other embodiments, the IaaS systems may have more or fewer components than shown in the figures, may combine two or more components, or may have a different configuration or arrangement of components.

In certain embodiments, the IaaS systems described herein may include a suite of applications, middleware, and database service offerings that are delivered to a customer in a self-service, subscription-based, elastically scalable, reliable, highly available, and secure manner. An example of such an IaaS system is the Oracle Cloud Infrastructure (OCI) provided by the present assignee.

### Hardware Overview

According to one embodiment, the techniques described herein are implemented by one or more special-purpose computing devices. The special-purpose computing devices may be hard-wired to perform the techniques, or may include digital electronic devices such as one or more application-specific integrated circuits (ASICs), field programmable gate arrays (FPGAs), or network processing units (NPUs) that are persistently programmed to perform the techniques, or may include one or more general purpose hardware processors programmed to perform the techniques pursuant to program instructions in firmware, memory, other storage, or a combination. Such special-purpose computing devices may also combine custom hard-wired logic, ASICs, FPGAs, or NPUs with custom programming to accomplish the techniques. The special-purpose computing devices may be desktop computer systems, portable computer systems, handheld devices, networking devices or any other device that incorporates hard-wired and/or program logic to implement the techniques.

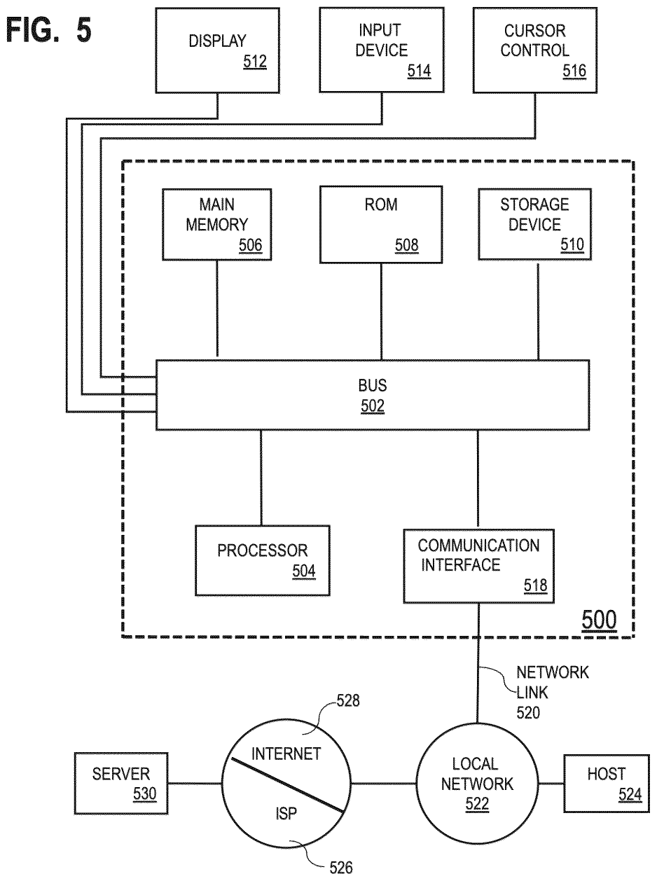

For example, FIG. 5 is a block diagram that illustrates a computer system 500 upon which an embodiment of the disclosure may be implemented. Computer system 500 includes a bus 502 or other communication mechanism for communicating information, and a hardware processor 504 coupled with bus 502 for processing information. Hardware processor 504 may be, for example, a general purpose microprocessor.

Computer system 500 also includes a main memory 506, such as a random access memory (RAM) or other dynamic storage device, coupled to bus 502 for storing information and instructions to be executed by processor 504. Main memory 506 also may be used for storing temporary variables or other intermediate information during execution of instructions to be executed by processor 504. Such instructions, when stored in non-transitory storage media accessible to processor 504, render computer system 500 into a special-purpose machine that is customized to perform the operations specified in the instructions.

Computer system 500 further includes a read-only memory (ROM) 508 or other static storage device coupled to bus 502 for storing static information and instructions for processor 504. A storage device 510, such as a magnetic disk, optical disk, or a solid-state drive (SSD) is provided and coupled to bus 502 for storing information and instructions.

Computer system 500 may be coupled via bus 502 to a display 512, such as a cathode ray tube (CRT), for displaying information to a computer user. An input device 514, including alphanumeric and other keys, is coupled to bus 502 for communicating information and command selections to processor 504. Another type of user input device is cursor control 516, such as a mouse, a trackball, or cursor direction keys for communicating direction information and command selections to processor 504 and for controlling cursor movement on display 512. This input device typically has two degrees of freedom in two axes, a first axis (e.g., x) and a second axis (e.g., y), that allows the device to specify positions in a plane.

Computer system 500 may implement the techniques described herein using customized hard-wired logic, one or more ASICs or FPGAs, firmware and/or program logic which in combination with the computer system causes or programs computer system 500 to be a special-purpose machine. According to one embodiment, the techniques herein are performed by computer system 500 in response to processor 504 executing one or more sequences of one or more instructions contained in main memory 506. Such instructions may be read into main memory 506 from another storage medium, such as storage device 510. Execution of the sequences of instructions contained in main memory 506 causes processor 504 to perform the process steps described herein. In alternative embodiments, hard-wired circuitry may be used in place of or in combination with software instructions.

The term “storage media” as used herein refers to any non-transitory media that store data and/or instructions that cause a machine to operate in a specific fashion. Such storage media may comprise non-volatile media and/or volatile media. Non-volatile media includes, for example, optical or magnetic disks, such as storage device 510. Volatile media includes dynamic memory, such as main memory 506. Common forms of storage media include, for example, a floppy disk, a flexible disk, hard disk, SSD, magnetic tape, or any other magnetic data storage medium, a CD-ROM, any other optical data storage medium, any physical medium with patterns of holes, a RAM, a PROM, and EPROM, a FLASH-EPROM, NVRAM, any other memory chip or cartridge, content-addressable memory (CAM), and ternary content-addressable memory (TCAM).

Storage media is distinct from but may be used in conjunction with transmission media. Transmission media participates in transferring information between storage media. For example, transmission media includes coaxial cables, copper wire and fiber optics, including the wires that comprise bus 502. Transmission media can also take the form of acoustic or light waves, such as those generated during radio-wave and infrared data communications.

Various forms of media may be involved in carrying one or more sequences of one or more instructions to processor 504 for execution. For example, the instructions may initially be carried on a magnetic disk or SSD of a remote computer. The remote computer can load the instructions into its dynamic memory and send the instructions over a telephone line using a modem. A modem local to computer system 500 can receive the data on the telephone line and use an infrared transmitter to convert the data to an infrared signal. An infrared detector can receive the data carried in the infrared signal and appropriate circuitry can place the data on bus 502. Bus 502 carries the data to main memory 506, from which processor 504 retrieves and executes the instructions. The instructions received by main memory 506 may optionally be stored on storage device 510 either before or after execution by processor 504.

Computer system 500 also includes a communication interface 518 coupled to bus 502. Communication interface 518 provides a two-way data communication coupling to a network link 520 that is connected to a local network 522. For example, communication interface 518 may be an integrated services digital network (ISDN) card, cable modem, satellite modem, or a modem to provide a data communication connection to a corresponding type of telephone line. As another example, communication interface 518 may be a local area network (LAN) card to provide a data communication connection to a compatible LAN. Wireless links may also be implemented. In any such implementation, communication interface 518 sends and receives electrical, electromagnetic or optical signals that carry digital data streams representing various types of information.

Network link 520 typically provides data communication through one or more networks to other data devices. For example, network link 520 may provide a connection through local network 522 to a host computer 524 or to data equipment operated by an Internet Service Provider (ISP) 526. ISP 526 in turn provides data communication services through the worldwide packet data communication network now commonly referred to as the “Internet” 528. Local network 522 and Internet 528 both use electrical, electromagnetic or optical signals that carry digital data streams. The signals through the various networks and the signals on network link 520 and through communication interface 518, which carry the digital data to and from computer system 500, are example forms of transmission media.

Computer system 500 can send messages and receive data, including program code, through the network(s), network link 520 and communication interface 518. In the Internet example, a server 530 might transmit a requested code for an application program through Internet 528, ISP 526, local network 522 and communication interface 518.

The received code may be executed by processor 504 as it is received, and/or stored in storage device 510, or other non-volatile storage for later execution.

### Data Center Cooling System Architecture

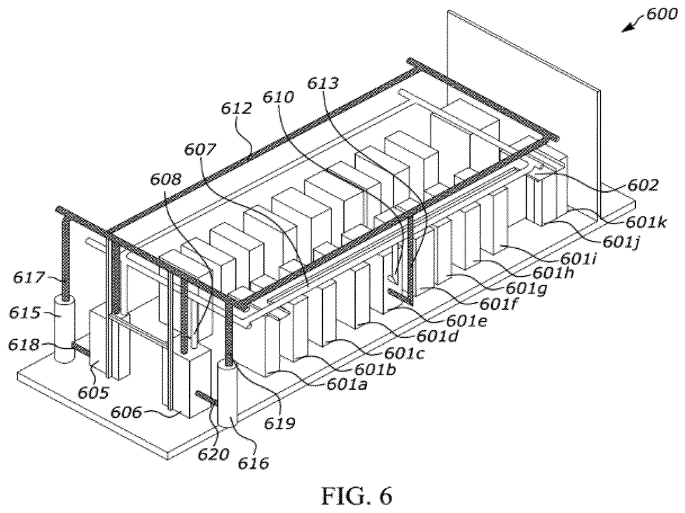

FIG. 6 illustrates a data center system 600 in accordance with one or more embodiments. As illustrated in FIG. 6, system 600 includes a set of racks 601a-601k. The racks 601a-601k may store computing devices, such as servers and switches, that generate heat. The system 600 include containers 602, such as trays, for holding cables to connect to the computing devices stored in the racks 601a-601k.

Cooling units 605 and 606 receive a flow of heated coolant liquid, cool the heated coolant liquid, and release the cooled coolant liquid to cool the computing devices in the racks 601a-601k. A cooling system includes an egress pipe 608 to direct the flow of the coolant liquid from the cooling unit 606 to a cooling pipe 607. In the example embodiment illustrated in FIG. 6, the cooling pipe is configured as a loop. The cooling unit 606 directs coolant liquid into the cooling pipe 607 at one position along the loop, and the cooling unit 605 directs coolant liquid into the cooling pipe 607 at another position along the loop.

A connector pipe 610 connects the cooling pipe 607 to the rack 601d. While a single connector pipe 610 is illustrated for purposes of clarity, the system 600 includes a connector pipe connected between the cooling pipe 607 and each of the racks 601a-601k, respectively.

An exhaust connector pipe 613 extends from the rack to the exhaust pipe 612. The exhaust pipe 612 carries the coolant liquid that has been heated by the computing devices stored in the racks 601a-601k toward the cooling units 605 and 606.

The system includes buffer tanks 615 and 616 along a liquid flow path between the exhaust pipe 612 and the cooling units 605 and 606. A connector pipe 619 connects the exhaust pipe 612 to the buffer tank 616. A connector pipe 617 connects the exhaust pipe 612 to the buffer tank 615. A connector pipe 620 connects the buffer tank 616 to the cooling unit 606. A connector pipe 618 connects the buffer tank 615 to the cooling unit 605.

The buffer tank 616 stores a reservoir of coolant liquid. As the buffer tank 616 receives exhaust coolant liquid from the exhaust pipe 612, the exhaust coolant liquid mixes with the reservoir of coolant liquid prior to flowing toward the cooling unit 606. The mixing of the exhaust coolant liquid with the reservoir of coolant liquid causes the temperature of the mixed coolant liquid directed toward the cooling unit 606 to change compared to the temperature of the exhaust coolant liquid entering the buffer tank 616. For example, if the exhaust coolant liquid is at a relatively high temperature compared to the reservoir coolant liquid, the temperature of the mixed coolant liquid directed toward the cooling unit 606 is lower than the temperature of the exhaust coolant liquid entering the buffer tank 616. Conversely, if the exhaust coolant liquid is at a relatively low temperature compared to the reservoir coolant liquid, the temperature of the mixed coolant liquid directed toward the cooling unit 606 is higher than the temperature of the exhaust coolant liquid entering the buffer tank 616. In this manner, the temperature of the mixed coolant liquid directed to the cooling unit 606 from the buffer tank 616 is continuously changing based on (a) the temperature of the exhaust coolant liquid entering the buffer tank 616 and (b) the temperature of the reservoir of coolant liquid in the buffer tank 616. The mixing of the exhaust coolant liquid with the reservoir coolant liquid has an effect of smoothing out temperature spikes in the mixed coolant liquid supplied to the cooling unit 606.

Application No. Ser. No. 19/423,778 filed Dec. 17, 2025 (the '778 application) is hereby incorporated by reference in its entirety to the same extent as if fully and explicitly recited herein. Any incorporation by reference is limited such that no subject matter is incorporated that is contrary to the explicit disclosure herein. FIG. 3A of the '778 application is a perspective view of a data center pod in accordance with one or more embodiments; FIG. 3B of the '778 application is a side view of a data center pod in accordance with one or more embodiments; FIG. 3C of the '778 application is a side view of an interconnectable data center pod module in accordance with one or more embodiments; FIG. 3D of the '778 application is an end view of an interconnectable data center pod module in accordance with one or more embodiments; and FIG. 3E of the '778 application is a cut-out view of an interconnectable data center pod module in accordance with one or more embodiments.

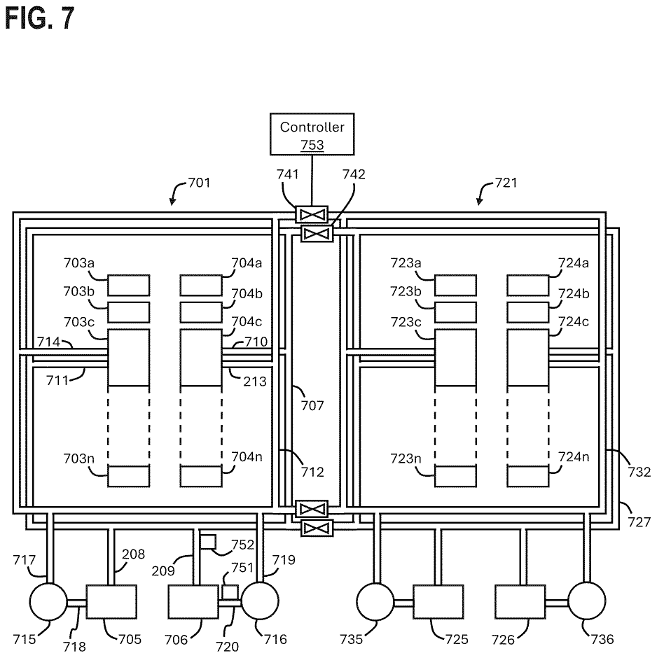

FIG. 7 illustrates an example of a data center system 700 according to another embodiment. The data center system 700 includes a set of racks 703a-703n and 704a-704n. The racks 703a-703n and 704a-704n may store computing devices, such as servers and switches, that generate heat.

Cooling units 705 and 706 receive a flow of heated coolant liquid, cool the heated coolant liquid, and release the cooled coolant liquid to cool the computing devices in the racks 703a-703n and 704a-704n. A cooling system includes an egress pipe 708 to direct the flow of the coolant liquid from the cooling unit 705 to a cooling pipe 707. An egress pipe 709 to direct the flow of the coolant liquid from the cooling unit 706 to a cooling pipe 707.

In the example embodiment illustrated in FIG. 7, the cooling pipe 707 is configured as a loop. The cooling unit 706 directs coolant liquid into the cooling pipe 707 at one position along the loop, and the cooling unit 705 directs coolant liquid into the cooling pipe 707 at another position along the loop.

A connector pipe 710 connects the cooling pipe 707 to the rack 704c. While a single connector pipe 710 is illustrated for purposes of clarity, the system 700 includes a connector pipe connected between the cooling pipe 707 and each of the racks 704a-704n, respectively. A connector pipe 711 connects the cooling pipe 707 to the rack 703c. While a single connector pipe 711 is illustrated for purposes of clarity, the system 700 includes a connector pipe connected between the cooling pipe 707 and each of the racks 703a-703n, respectively.

An exhaust connector pipe 713 extends from the rack 704c to the exhaust pipe 712. An exhaust connector pipe 714 extends from the rack 703c to the exhaust pipe 712. The exhaust pipe 712 carries the coolant liquid that has been heated by the computing devices stored in the racks 703a-703n and 704a-704n toward the cooling units 705 and 706.

The system includes buffer tanks 715 and 716 along a liquid flow path between the exhaust pipe 712 and the cooling units 705 and 706. A connector pipe 719 connects the exhaust pipe 712 to the buffer tank 716. A connector pipe 717 connects the exhaust pipe 712 to the buffer tank 715. A connector pipe 720 connects the buffer tank 716 to the cooling unit 706. A connector pipe 718 connects the buffer tank 715 to the cooling unit 705.

The buffer tank 716 stores a reservoir of coolant liquid. As the buffer tank 716 receives exhaust coolant liquid from the exhaust pipe 712, the exhaust coolant liquid mixes with the reservoir of coolant liquid prior to flowing toward the cooling unit 706. The buffer tank 715 stores a reservoir of coolant liquid. As the buffer tank 715 receives exhaust coolant liquid from the exhaust pipe 712, the exhaust coolant liquid mixes with the reservoir of coolant liquid prior to flowing toward the cooling unit 705.

The system includes a first data center pod 701 and a second data center pod 702. The first data center pod 701 includes a first set of racks, computing devices, cooling pipes, buffer tanks, and cooling units. The second data center pod 721 includes a first set of racks, computing devices, cooling pipes, buffer tanks, and cooling units.

The second data center pod 721 includes racks 723a-723n and 724a-724n. A cooling pipe 727 provides cooling liquid from cooling units 725 and 726 to the racks 723a-723n and 724a-724n. An exhaust pipe 732 supplies exhaust coolant liquid, that has been heated by computing devices in the racks 723a-723n and 724a-724n, to the cooling units 725 and 726. Buffer tanks 735 and 736 are located along a flow path between the exhaust pipe 732 and the cooling units 725 and 726. The exhaust coolant liquid from the exhaust pipe 732 mixes with reservoir coolant liquid in the buffer tanks 735 and 736 prior to flowing to the cooling units 725 and 726.

The system includes a sensor 751. Sensor 751 may be located on, or in, the connector pipe 720 to detect a temperature of the mixed coolant liquid flowing to the cooling unit 706. A controller 753 receives the sensor data from the sensor 751. If the temperature detected by the sensor 751 exceeds a threshold, the controller 753 may open valve 741 to allow a flow of exhaust coolant liquid between exhaust pipes 712 and 732. The mixing of the exhaust coolant liquid between exhaust pipes 712 and 732 may have an effect of smoothing out temperature spikes in the mixed coolant liquid supplied to the cooling unit 706.

In an embodiment, controller 753 is implemented on one or more digital devices. The term “digital device” generally refers to any hardware device that includes a processor. A digital device may refer to a physical device executing an application or a virtual machine. Examples of digital devices include a computer, a tablet, a laptop, a desktop, a netbook, and a server.

The system includes a sensor 752. Sensor 752 may be located on, or in, the connector pipe 709 to detect a temperature of the coolant liquid flowing out from the cooling unit 706. The controller 753 receives the sensor data from the sensor 752. If the temperature detected by the sensor 752 exceeds a threshold, the controller 753 may open valve 742 to allow a flow of coolant liquid between cooling pipes 707 and 727. The mixing of the coolant liquid between cooling pipes 707 and 727 may have an effect of smoothing out temperature spikes in the cooling liquid supplied to the racks 703a-703n and 704a-704n.

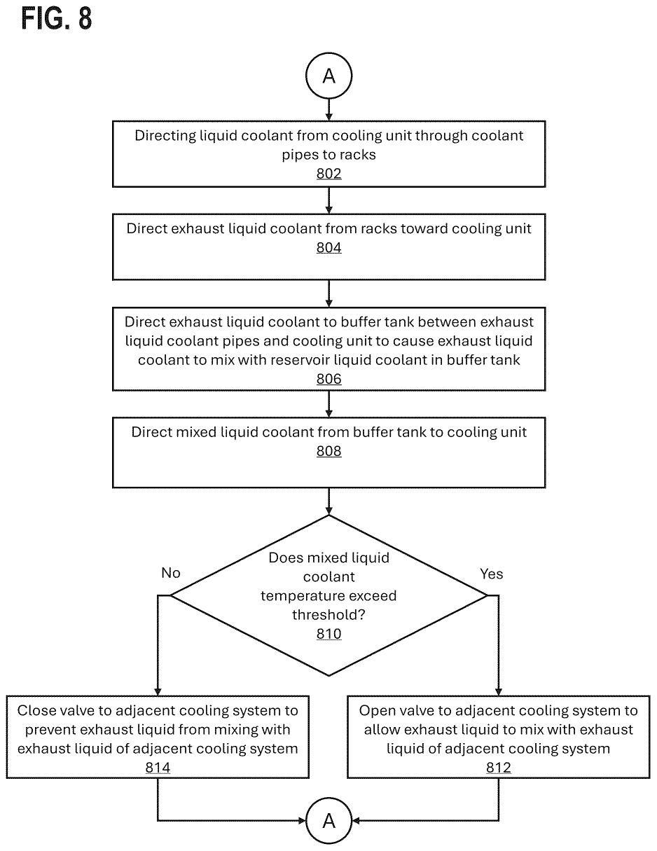

In one or more embodiments, controller 753 refers to hardware and/or software configured to perform operations described herein for controlling valves 741 and 742 to permit or prevent the flow of coolant liquid between data center pods 701 and 721. Examples of operations for using a buffer tank in a liquid cooling system for a data center are described below with reference to FIG. 8.

### Managing Temperature Spikes Using a Buffer Tank in a Liquid Cooling System

FIG. 8 illustrates an example set of operations for using buffer tanks in a liquid cooling system in accordance with one or more embodiments. One or more operations illustrated in FIG. 8 may be modified, rearranged, or omitted. Accordingly, the particular sequence of operations illustrated in FIG. 8 should not be construed as limiting the scope of one or more embodiments.

In an embodiment, the system directs a coolant liquid flow from a cooling unit through cooling pipes to rack units in a data center (Operation 802). The cooling unit may include a pump, or the system may include a pump external to the cooling unit. The cooling unit may include a heat exchanger element that takes in heated coolant liquid, cools the heated coolant liquid, and outputs cooled coolant liquid. For example, a chiller plant may provide the cooling unit with a continuous stream of cooled water. Pipes carrying the cooled water may abut pipes carrying the heated coolant liquid in the heat exchanger. The heat exchanger may facilitate a heat transfer process whereby the cooled water cools the heated coolant liquid.

The system may include connector pipes to direct the flow of coolant liquid to racks. The system may further include additional pipes, tubes, or other containers to direct the flow of the coolant liquid across heat-generating elements of computing devices, such as across central processing units (CPUs) and graphics processing units (GPUs).

The system directs heated coolant liquid from racks toward the cooling unit (Operation 804). As the coolant liquid flows over heating components in computing devices, the heating components heat the coolant liquid. The heated coolant liquid flowing away from the heating components is described herein as exhaust coolant liquid.

The system directs the exhaust coolant liquid to a buffer tank located along a flow path between an exhaust coolant liquid pipe and the cooling unit (Operation 806). The buffer tank stores a reservoir of coolant liquid. As the buffer tank receives exhaust coolant liquid from an exhaust pipe, the exhaust coolant liquid mixes with the reservoir of coolant liquid prior to flowing toward the cooling unit. The mixing of the exhaust coolant liquid with the reservoir of coolant liquid causes the temperature of the mixed coolant liquid directed toward the cooling unit to change compared to the temperature of the exhaust coolant liquid entering the buffer tank. For example, if the exhaust coolant liquid is at a relatively high temperature compared to the reservoir coolant liquid, the temperature of the mixed coolant liquid directed toward the cooling unit is lower than the temperature of the exhaust coolant liquid entering the buffer tank. Conversely, if the exhaust coolant liquid is at a relatively low temperature compared to the reservoir coolant liquid, the temperature of the mixed coolant liquid directed toward the cooling unit is higher than the temperature of the exhaust coolant liquid entering the buffer tank. In this manner, the temperature of the mixed coolant liquid directed to the cooling unit from the buffer tank is continuously changing based on (a) the temperature of the exhaust coolant liquid entering the buffer tank and (b) the temperature of the reservoir of coolant liquid in the buffer tank. The mixing of the exhaust coolant liquid with the reservoir coolant liquid has an effect of smoothing out temperature spikes in the mixed coolant liquid supplied to the cooling unit.

The system directs the mixed exhaust coolant liquid from the buffer tank to the cooling unit (Operation 808). The mixed exhaust coolant liquid has a temperature that is based on mixing the exhaust coolant liquid with the reservoir coolant liquid in the buffer tank.

The system determines if the temperature of the mixed exhaust coolant liquid exceeds a threshold (Operation 810). In an embodiment, the system includes a sensor to determine a temperature of the mixed exhaust coolant liquid. The threshold may be based on performance specifications of (a) computing devices, (b) the cooling unit, or (c) a chiller unit that supplies cooling water to the cooling unit. For example, a chiller unit may be configured to shut down or pause operations if a temperature of water returning to the chiller unit exceeds a specified temperature. The threshold temperature may be selected to prevent the temperature of the water returning to the chiller unit from exceeding the specified temperature.

If the system determines the temperature of the mixed exhaust coolant liquid exceeds the threshold, the system opens a valve to an adjacent cooling system (Operation 812). The adjacent cooling system may be configured to cool a set of racks storing computing devices in an adjacent row, pod, or group of computing devices in a data center. When the valve is closed, each cooling system may be configured to cool a separate set of computing devices stored in separate racks independently of each other. When the valve is opened, the system may permit exhaust cooling fluid to mix between the cooling systems. The mixing of the exhaust coolant liquid between exhaust coolant liquid pipes of the adjacent cooling systems may have an effect of smoothing out temperature spikes in the cooling liquid supplied to the racks cooled by the respective cooling systems.

If the system determines the temperature of the mixed exhaust coolant liquid does not exceed the threshold, the system closes the valve to the adjacent cooling system (Operation 814). Closing the valve prevents the mixing of exhaust cooling fluid between the adjacent cooling systems to allow for individualized cooling of the computing devices in adjacent pods, rows, or device groups associated with the adjacent cooling systems.

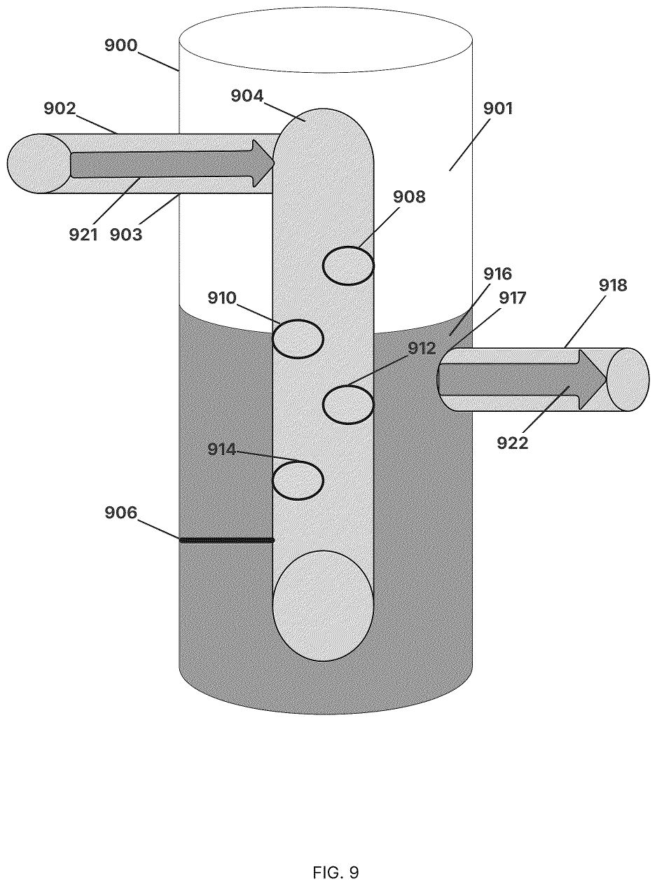

FIG. 9 illustrates a buffer tank in accordance with one or more embodiments. The buffer tank 900 includes a first set of one or more pipes 902 of one or more pipes that passes incoming liquid 921 from a target object to a vessel 901 within the buffer tank 900 that holds a liquid 916 having a first heat energy. The liquid 916 may be provided by an external source using one or more pipes (not illustrated). The buffer tank 900 includes a second set of one or more pipes 918 that passes outgoing liquid 922 from the buffer tank 900 to a cooling unit (not illustrated). In one or more embodiments, a size of the area of the first set of one or more pipes 902 is equal to a size of the area of the second set of one or more pipes 918.

The buffer tank 900 includes the vessel 901 that holds a body of liquid 916 having the first heat energy. The buffer tank 900 includes a first opening 903 connected to or integrated into a liquid distribution component 904 that passes incoming liquid 921 from the first set of pipes 902, the incoming liquid having a second heat energy.

The buffer tank 900 includes a liquid distribution component 904 within the vessel 901 that distributes the incoming liquid 921 to several points corresponding to openings 908, 910, 912, and 914 within the vessel 901, so diffusion between the first heat energy of the body of liquid 916 and the second heat energy of the incoming liquid 921 from the first set of one or more pipes 902 occurs at the several points corresponding to openings 908, 910, 912, and 914. The number of openings 908, 910, 912, and 914 may be determined based on a configuration that provides an optimal and/or maximum amount of mixing within the vessel 901. Accordingly, different liquid distribution components may include a different number of openings based on the requirements of specific applications in accordance with one or more embodiments. The buffer tank 900 includes fixing components 906 that fix the liquid distribution component 904 within the vessel 901.

The buffer tank 900 includes a second opening 917 within the vessel 901 that passes outgoing liquid 922 to the second set of one or more pipes 918, the outgoing liquid 922 having a third heat energy between the first heat energy and the second heat energy. For example, if the incoming liquid has a temperature of 60 degrees Celsius (e.g., hot water), and the buffered liquid has a temperature of 15 degrees Celsius (e.g., cold water), the outgoing liquid will have a temperature between 60 degrees Celsius and 15 degrees Celsius, based on the mixing effect of the hot water with the cold water.

In one or more embodiments, a first rate of change in the second heat energy of the incoming liquid 921 is greater than a second rate of change in the third heat energy of the outgoing liquid 922. For example, if the incoming liquid is being quickly heated such that the first rate of change in the second heat energy of the incoming liquid increases by 10 degrees Celsius per minute and the heat energy of the buffered liquid is less than the heat energy of the incoming liquid, then the second rate of change in the third heat energy of the outgoing liquid may increase by a lesser rate than 10 degrees Celsius per minute due to the mixing of the incoming liquid with a cooler buffered liquid. In one or more embodiments, the cooling unit may be associated with a maximum rate of change in a heat energy of the liquid entering from the second set of one or more pipes 918 into the cooling unit. The first rate of change in the second heat energy of the incoming liquid 921 is caused by heat produced by one or more target objects. A second rate of change in the third heat energy of the outgoing liquid 922 is caused by diffusion of the second heat energy within the buffer tank 900. In one or more embodiments, a first rate of change in the second heat energy of the incoming liquid 921 is greater than a maximum rate of change sustainable by the cooling unit.

In one or more embodiments, during a first time period, the second heat energy of the incoming liquid 921 is greater than the first heat energy of the body of liquid 916, and the diffusion causes an increase in the first heat energy of the body of liquid 916. During a second time period, the second heat energy of the incoming liquid 921 is lower than the heat energy of the body of liquid 916, and the diffusion causes a decrease in the first heat energy of the body of liquid 916.

In one or more embodiments, the second heat energy of the incoming liquid 921 is greater than the third heat energy of the outgoing liquid 922. For example, the incoming liquid 921 is at a higher temperature of 60 degrees Celsius and the outgoing liquid is at a lower temperature of 40 degrees Celsius (e.g., the outgoing temperature is lower due to the mixing of the incoming liquid 921 with the body of liquid 916 where the body of liquid is at a lower temperature than the incoming liquid 921).

In one or more embodiments, the cooling unit is associated with a maximum heat energy of the liquid entering from the second set of pipes 918 into the cooling unit. For example, the cooling unit is associated with a maximum temperature of 60 degrees Celsius for liquid entering from the second set of pipes 918 into the cooling unit.

In one or more embodiments, the second heat energy of the incoming liquid 921 is greater than a maximum heat energy of the liquid entering from the second set of pipes 918 into the cooling unit that is sustainable by the cooling unit. For example, the incoming liquid 921 is at 65 degrees Celsius which is greater than a maximum temperature of 60 degree Celsius for liquid entering from the second set of pipes 918 into the cooling unit that is sustainable by the cooling unit.

In one or more embodiments, the second heat energy of the incoming liquid 921 is caused by heat produced by one or more target objects (not illustrated) and the third heat energy of the outgoing liquid 922 is caused at least by diffusion of the second heat energy within the buffer tank 900. In one or more embodiments, the target objects include one or more computing devices that experience synchronous changes in heat energy, in particular, as associated with machine learning (ML) workloads. During large synchronous machine learning workloads, computing devices in server farms generate intense and sustained heat because GPUs and other accelerators operate at near-maximum utilization while staying synchronized across many nodes. In synchronous training, one or more devices (e.g., all devices) compute at the same time and periodically exchange gradients, which causes power draw to spike simultaneously across servers and racks. The electrical power is converted into heat, which is removed continuously to prevent thermal throttling or hardware damage.

In one or more embodiments, the liquid distribution component 904 within the vessel 901 distributes the incoming liquid 921 through openings 908, 910, 912, and 914 within the vessel 901 at different depths within the vessel 901. In one or more embodiments, the openings 908, 910, 912, and 914 are randomly distributed within the liquid distribution component. In certain embodiments, the openings 908, 910, 912, and 914 may be distributed using a predetermined pattern along the liquid distribution component 904. In one or more embodiments, a total size of the area of the openings 908, 910, 912, and 914 is equal to a size of the area of first set of one or more pipes 902.

In one or more embodiments, the liquid distribution component 904 is a cylindrical shape. In one or more embodiments, the first opening 903 is located higher along a side of the buffer tank 900 than the second opening 917.

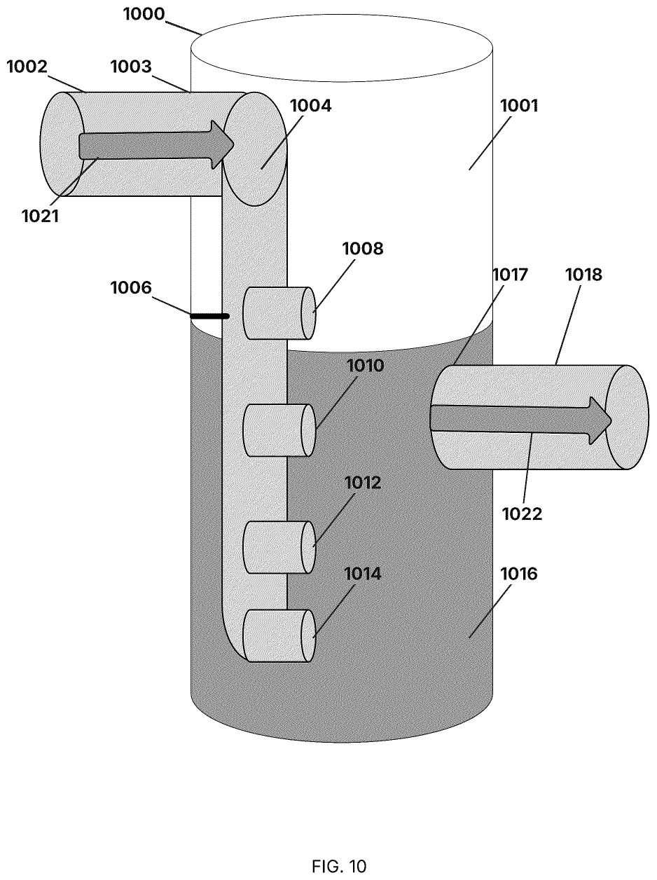

FIG. 10 illustrates a buffer tank in accordance with one or more embodiments. The buffer tank 1000 illustrated in FIG. 10 is similar to the buffer tank of FIG. 9; however, the liquid distribution component 1004 includes several pipes (1008, 1010, 1012, and 1014) that distribute the incoming liquid 1021 within the vessel 1001 of the buffer tank 1000. The buffer tank 1000 includes a first set of one or more pipes 1002 of one or more pipes that passes incoming liquid 1021 from a target object to a vessel 1001 within the buffer tank 1000 that holds a liquid 1016 having a first heat energy. The buffer tank 1000 includes a second set of one or more pipes 1018 that passes outgoing liquid 1022 from the buffer tank 1000 to a cooling unit (not illustrated). The buffer tank 1000 includes the vessel 1001 that holds a body of liquid 1016 having the first heat energy. The buffer tank 1000 includes a first opening 1003 connected to or integrated into a liquid distribution component 1004 that passes incoming liquid 1021 from the first set of pipes 1002, the incoming liquid having a second heat energy.

The buffer tank 1000 includes a liquid distribution component 1004 within the vessel 1001 that distributes the incoming liquid 1021 to several pipes (1008, 1010, 1012, and 1014) within the vessel 1001, so diffusion between the first heat energy of the body of liquid 1016 and the second heat energy of the incoming liquid 1021 from the first set of one or more pipes 1002 occurs at the several points corresponding to the pipes 1008, 1010, 1012, and 1014. The number of pipes 1008, 1010, 1012, and 1014 may be determined based on a configuration that provides an optimal and/or maximum amount of mixing within the vessel 1001. The buffer tank 1000 includes fixing components 1006 that fix the liquid distribution component 1004 within the vessel 1001.

The buffer tank 1000 includes a second opening 1017 within the vessel 1001 that passes outgoing liquid 1022 to the second set of one or more pipes 1018, the outgoing liquid 1022 has a third heat energy between the first heat energy and the second heat energy. In one or more embodiments, a first rate of change in the second heat energy of the incoming liquid 1021 is greater than a second rate of change in the third heat energy of the outgoing liquid 1022. The cooling unit (not illustrated) may be associated with a maximum rate of change in a heat energy of the liquid entering from the second set of one or more pipes 1018 into the cooling unit. The first rate of change in the second heat energy of the incoming liquid 1021 is caused by heat produced by one or more target objects. A second rate of change in the third heat energy of the outgoing liquid 1022 is caused by diffusion of the second heat energy within the buffer tank 1000. In one or more embodiments, a first rate of change in the second heat energy of the incoming liquid 1021 is greater than a maximum rate of change sustainable by the cooling unit.

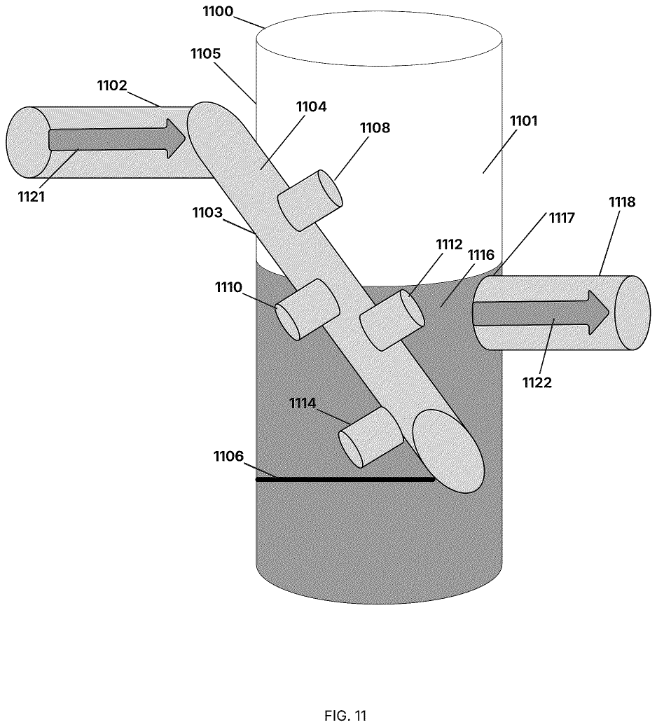

FIG. 11 illustrates a buffer tank in accordance with one or more embodiments. The buffer tank 1100 illustrated in FIG. 11 is similar to the buffer tank of FIG. 9; however, the liquid distribution component 1104 is sloped relative to a vertical side wall 1105 of the buffer tank 1100.

The buffer tank 1100 includes a first set of one or more pipes 1102 of one or more pipes that passes incoming liquid 1121 from a target object to a vessel 1101 within the buffer tank 1100 that holds a liquid 1116 having a first heat energy. The buffer tank 1100 includes a second set of one or more pipes 1118 that passes outgoing liquid 1122 from the buffer tank 1000 to a cooling unit (not illustrated). The buffer tank 1100 includes the vessel 1101 that holds a body of liquid 1116 having the first heat energy. The buffer tank 1100 includes a first opening 1103 connected to or integrated into a liquid distribution component 1104 that passes incoming liquid 1121 from the first set of pipes 1102, and the incoming liquid 1121 has a second heat energy.

The buffer tank 1100 includes a sloped liquid distribution component 1104 within the vessel 1101 that distributes the incoming liquid 1121 to several pipes (1108, 1110, 1112, and 1114) within the vessel 1101, so diffusion between the first heat energy of the body of liquid 1116 and the second heat energy of the incoming liquid 1121 from the first set of one or more pipes 1102 occurs at the several points corresponding to the pipes 1108, 1110, 1112, and 1114. The liquid distribution component 1104 is sloped relative to a vertical side wall 1105 of the buffer tank 1100 where the slope causes the incoming liquid 1121 to generate a spinning effect with the liquid 1116, improving mixing between the liquids. The buffer tank 1100 includes fixing components 1106 that fix the liquid distribution component 1104 within the vessel 1101.

The buffer tank 1100 includes a second opening 1117 within the vessel 1101 that passes outgoing liquid 1122 to the second set of one or more pipes 1118, the outgoing liquid 1122 has a third heat energy between the first heat energy and the second heat energy. In one or more embodiments, a first rate of change in the second heat energy of the incoming liquid 1121 is greater than a second rate of change in the third heat energy of the outgoing liquid 1122. The cooling unit (not illustrated) may be associated with a maximum rate of change in a heat energy of the liquid entering from the second set of one or more pipes 1118 into the cooling unit. The first rate of change in the second heat energy of the incoming liquid 1121 is caused by heat produced by one or more target objects. A second rate of change in the third heat energy of the outgoing liquid 1122 is caused by diffusion of the second heat energy within the buffer tank 1100. In one or more embodiments, a first rate of change in the second heat energy of the incoming liquid 1121 is greater than a maximum rate of change sustainable by the cooling unit.

### Practical Applications, Advantages, and Improvements

Embodiments provide several practical applications, advantages, and improvements over existing approaches. These advantages and improvements include reducing temperature spikes of a coolant liquid relative to an incoming liquid by reducing a rate of temperature change of the coolant liquid that is provided to a cooling unit relative to a rate of temperature change of an incoming exhaust liquid generated by a target object, reducing spikes in temperature of the coolant liquid provided to the cooling unit.

Embodiments may reduce a rate of temperature change of an outgoing liquid relative to a rate of temperature change of an incoming liquid by using a buffer tank that includes a liquid at a first heat energy and a liquid distribution component that distributes an incoming liquid at a second heat energy at multiple points within a vessel of the buffer tank, so diffusion between the first heat energy of the body of liquid and the second heat energy of the incoming liquid occurs at multiple points. Thus, an outgoing liquid is output to a cooling unit where the outgoing liquid may have a reduced rate of temperature change relative to the rate of temperature change of the incoming liquid. Embodiments also control a heat energy of an outgoing liquid relative to a heat energy of incoming liquid, where the heat energy of the outgoing liquid is reduced relative to the heat energy of the incoming liquid when the heat energy of incoming liquid is greater than a heat energy of a buffered liquid in a buffer tank (e.g., hot incoming liquid is mixed with a cooler buffered liquid in the buffer tank to output a less hot outgoing liquid).

### Miscellaneous; Extensions

Unless otherwise defined, all terms (including technical and scientific terms) are to be given their ordinary and customary meaning to a person of ordinary skill in the art, and are not to be limited to a special or customized meaning unless expressly so defined herein.

This application may include references to certain trademarks. Although the use of trademarks is permissible in patent applications, the proprietary nature of the marks should be respected and every effort made to prevent their use in any manner which might adversely affect their validity as trademarks.

Embodiments are directed to a system with one or more devices that include a hardware processor and that are configured to perform any of the operations described herein and/or recited in any of the claims below.

In an embodiment, one or more non-transitory computer readable storage media comprises instructions which, when executed by one or more hardware processors, cause performance of any of the operations described herein and/or recited in any of the claims.

In an embodiment, a method comprises operations described herein and/or recited in any of the claims, the method being executed by at least one device including a hardware processor.

Any combination of the features and functionalities described herein may be used in accordance with one or more embodiments. In the foregoing specification, embodiments have been described with reference to numerous specific details that may vary from implementation to implementation. The specification and drawings are, accordingly, to be regarded in an illustrative rather than a restrictive sense. The sole and exclusive indicator of the scope of patent protection, and what is intended by the applicants to be the scope of patent protection, is the literal and equivalent scope of the set of claims that issue from this application, in the specific form in which such claims issue, including any subsequent correction.

What is claimed is:

1. A system comprising:
a first set of one or more pipes configured to pass liquid from one or more target objects to a first buffer tank;
a second set of one or more pipes configured to pass the liquid from the first buffer tank and a first cooling unit;
the first buffer tank comprising:
a vessel configured to hold a body of liquid having a first heat energy;
a first opening connected to a liquid distribution component configured to pass incoming liquid from the first set of pipes, the incoming liquid having a second heat energy;
the liquid distribution component within the vessel configured to distribute the incoming liquid to a plurality of points within the vessel such that diffusion between the first heat energy of the body of liquid and the second heat energy of the incoming liquid occurs at the plurality of points;
a second opening connected to the vessel configured to pass outgoing liquid to the second set of pipes, the outgoing liquid having a third heat energy between the first heat energy and the second heat energy.

2. The system of claim 1, wherein a first rate of change in the second heat energy of the incoming liquid is greater than a second rate of change in the third heat energy of the outgoing liquid.

3. The system of claim 1, wherein the first cooling unit is associated with a maximum rate of change in a heat energy of the liquid entering from the second set of pipes into the first cooling unit.

4. The system of claim 1, wherein a first rate of change in the second heat energy of the incoming liquid is greater than a maximum rate of change sustainable by the first cooling unit.

5. The system of claim 1, wherein the second heat energy of the incoming liquid is greater than the third heat energy of the outgoing liquid.

6. The system of claim 1, wherein the first cooling unit is associated a maximum heat energy of the liquid entering from the second set of pipes into the first cooling unit.

7. The system of claim 1, wherein the second heat energy of the incoming liquid is greater than a maximum heat energy of the liquid entering from the second set of pipes into the first cooling unit that is sustainable by the first cooling unit.

8. The system of claim 1, wherein the second heat energy of the incoming liquid is caused at least by heat produced by the one or more target objects, and the third heat energy of the outgoing liquid is caused at least by diffusion of the second heat energy within the first buffer tank.

9. The system of claim 1, wherein:
during a first time period, the second heat energy of the incoming liquid is greater than the first heat energy of the body of liquid, and the diffusion causes an increase in the first heat energy of the body of liquid; and
during a second time period, the second heat energy of the incoming liquid is lesser than the first heat energy of the body of liquid, and the diffusion causes a decrease in the first heat energy of the body of liquid.

10. The system of claim 1, wherein the liquid distribution component is positioned at a downward slope relative to a vertical side of the vessel.

11. The system of claim 1, wherein the liquid distribution component includes a plurality of openings that pass the incoming liquid to the plurality of points within the vessel.

12. The system of claim 11, wherein a combined area of the plurality of openings is approximately equal to an area of the first opening.

13. The system of claim 11, wherein a first opening of the plurality of openings and a second opening of the plurality of openings are positioned facing different directions within the vessel.

14. The system of claim 11, wherein the plurality of openings are randomly positioned along the liquid distribution component.

15. The system of claim 11, wherein an opening in the plurality of openings comprises a pipe.

16. The system of claim 1, wherein the liquid distribution component within the vessel distributes the incoming liquid to the plurality of points within the vessel at different depths within the vessel.

17. The system of claim 1, wherein the liquid distribution component is a cylindrical shape.

18. The system of claim 1, wherein the first opening is located higher along a side of the first buffer tank than the second opening.

19. The system of claim 1, wherein the one or more target objects comprise a plurality of computing devices that experience synchronous changes in heat energy.

20. A method comprising:
passing, using a first set of one or more pipes, liquid from one or more target objects to a first buffer tank;
passing, a second set of one or more pipes, the liquid from the first buffer tank and a first cooling unit;
wherein the first buffer tank comprises:
a vessel configured to hold a body of liquid having a first heat energy;
a first opening connected to a liquid distribution component configured to pass incoming liquid from the first set of pipes, the incoming liquid having a second heat energy;
the liquid distribution component within the vessel configured to distribute the incoming liquid to a plurality of points within the vessel such that diffusion between the first heat energy of the body of liquid and the second heat energy of the incoming liquid occurs at the plurality of points;
a second opening connected to the vessel configured to pass outgoing liquid to the second set of pipes, the outgoing liquid having a third heat energy between the first heat energy and the second heat energy.
